(19) United States
(12) Patent Application Publication
(10) Pub. No.: US 2007/0115709 A1
(43) Pub. Date: May 24, 2007

(54) Host computer memory configuration data remote access method and system

(75) Inventors: Wh Shih, Taipei (TW); Chin-Fong Pan, Taipei (TW)

Correspondence Address: FULBRIGHT AND JAWORSKI LLP, 555 S. FLOWER STREET, 41ST FLOOR, LOS ANGELES, CA, 90071, US

(73) Assignee: INVENTEC CORPORATION

(21) Appl. No.: 11/394,069

(22) Filed: Mar. 29, 2006

(30) Foreign Application Priority Data
Nov. 18, 2005 (TW) 94140534

(51) Int. Cl. G11C 5/06

(52) U.S. Cl. 365/63

(57) ABSTRACT

A host computer memory configuration data remote access method and system is proposed, which is designed for use with a client station and a host computer for the purpose of allowing a user at the client station to learn the current memory configuration of the host computer via the client station; and which is characterized by the capability of reading a set of embedded memory specification data from all the memory modules currently installed on the host computer, then using these memory specification data to automatically set up a suitable configuration for these memory modules, and subsequently transferring the memory configuration data to a host management control unit that is used to control the linking of the client station to the host computer. This feature allows network system management personnel to conveniently and quickly gain access to the memory configuration of the host computer from a client station.

### BACKGROUND OF THE INVENTION

1. Field of The Invention

This invention relates to information technology (IT), and more particularly, to a host computer memory configuration data remote access method and system which is designed for use in conjunction with a client station and a host computer, such as a network server, for the purpose of allowing a user (i.e., network system management personnel) at the client station to learn the current memory configuration of the network server remotely via the client workstation.

2. Description of Related Art

A network server is a centralized host computer that is linked to a network and capable of providing network-based data services via the network to one or more client stations. In the application of enterprise-class network servers, since these servers are used to handle extremely huge amounts of data, there is a standardized specification called RAS, which stands for Reliability, Accessibility, and Serviceability, for the design and manufacture of enterprise-class network servers. The RAS specification stipulates that an enterprise-class network server should have high level of reliability during operation, high level of accessibility for the clients, and high level of serviceability to serve the clients.

To meet the RAS requirements, enterprise-class network servers are customarily equipped with high-capacity memory modules, which are configured to provide various backup capabilities, such as mirroring and redundancy, and various high-speed access modes, such as dual-channel access mode and single-channel access mode. In practical implementation, enterprise-class network servers typically utilize DIMM (Dual Inline Memory Module) as primary memory.

Since an enterprise-class network server is typically installed with a large number of DIMM modules which might be set to different operating modes, the overall memory configuration of these DIMM modules would be highly complicated. This situation would make the network system management personnel hard to learn the current operating mode or status of each of the multiple DIMM modules installed on the network server; i.e., whether a particular DIMM module is enabled, disabled, or failed. If the network system management personnel is unaware of the memory configuration of a network server, the management personnel would be unable to manage the network server effectively.

### SUMMARY OF THE INVENTION

It is therefore an objective of this invention to provide a host computer memory configuration data remote access method and system which allows network system management personnel to learn the memory configuration of a network server conveniently via a client station linked to the network server.

The host computer memory configuration data remote access method and system according to the invention is designed for use in conjunction with a client station and a host computer, such as a network server, for the purpose of allowing a user (i.e., network system management personnel) at the client station to learn the current memory configuration of the network server remotely via the client workstation.

The host computer memory configuration data remote access method according to the invention comprises: (1) on the host computer, responding to a startup event on the host computer by reading a set of memory embedded specification data from the memory modules installed on the host computer; (2) on the host computer, configuring the memory modules based on the memory embedded specification data retrieved from the memory modules and generating a set of memory configuration data based on the configuration of the memory modules; (3) on the host computer, transferring the memory configuration data from the startup control unit to the host management control unit for storage in the host management control unit by way of a customized memory configuration data write command; (4) on the client station, responding to a user-initiated memory configuration data read requesting event by issuing a configuration data read requesting message; and (5) on the client station, responding to the configuration data read requesting message by issuing a customized configuration data read command to the host management control unit on the host computer, causing the host management control unit to respond by transferring the memory configuration data stored therein to the client station for display in a human-readable form on the client station.

The host computer memory configuration data remote access system according to the invention is based on a distributed architecture comprising: (A) a host-side unit; and (B) a client-side unit; wherein the host-side unit is installed on the host computer, and which includes: (A1) a memory embedded specification data reading module, which is capable of responding to a startup event on the host computer by reading a set of memory embedded specification data from the memory modules installed on the host computer; (A2) a memory configuration setting module, which is capable of configuring the memory modules based on the memory embedded specification data retrieved from the memory modules by the memory embedded specification data reading module, and further capable of generating a set of memory configuration data based on the configuration of the memory modules; and (A3) a configuration data transferring module, which is capable of transferring the memory configuration data generated by the memory configuration setting module from the startup control unit to the host management control unit for storage in the host management control unit by way of a customized memory configuration data write command; and wherein the client-side unit is installed the client station, and which includes: (B1) a user interface module, which is capable of responding to a user-initiated memory configuration data read requesting event by issuing a configuration data read requesting message; and (B2) a read command issuing module, which is capable of responding to the configuration data read requesting message by issuing a customized configuration data read command to the host management control unit on the host computer, causing the host management control unit to respond by transferring the memory configuration data stored therein to the user interface module for the user interface module to display the memory configuration data in a human-readable form on the client station.

The host computer memory configuration data remote access method and system according to the invention is characterized by the capability of reading a set of embedded memory specification data (such DIMM SPD data) from all the DIMM modules currently installed on the host computer, then using these memory specification data to automatically set up a suitable configuration for these memory modules, and subsequently transferring the memory configuration data from the BIOS unit to a BMC unit that is used to control the linking of the client station to the host computer, such that the client station can retrieve the memory configuration data from the BMC unit. This feature allows network system management personnel to conveniently and quickly gain access to and learn the memory configuration of the host computer from a client station linked to the host computer.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing the application and distributed architecture of the host computer memory configuration data remote access system of the invention; and

FIG. 2 is a schematic diagram showing the object-oriented component model of the host computer memory configuration data remote access system of the invention.

### DETAILED DESCRIPTION OF PREFERRED EMBODIMENTS

The host computer memory configuration data remote access method and system according to the invention is disclosed in full details by way of preferred embodiments in the following with reference to the accompanying drawings.

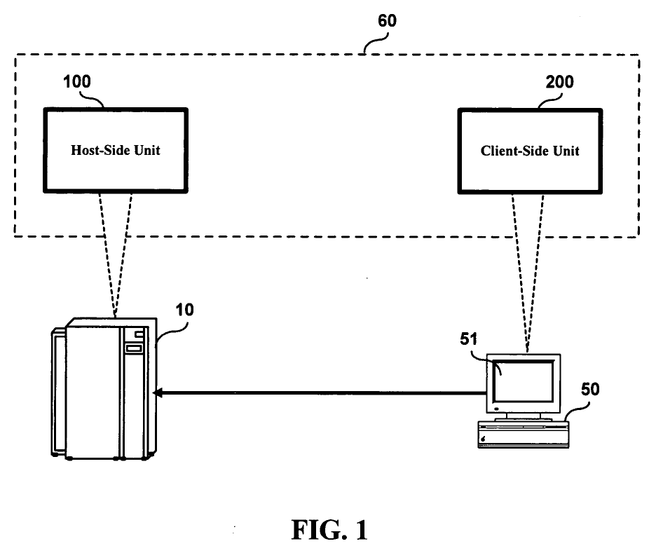

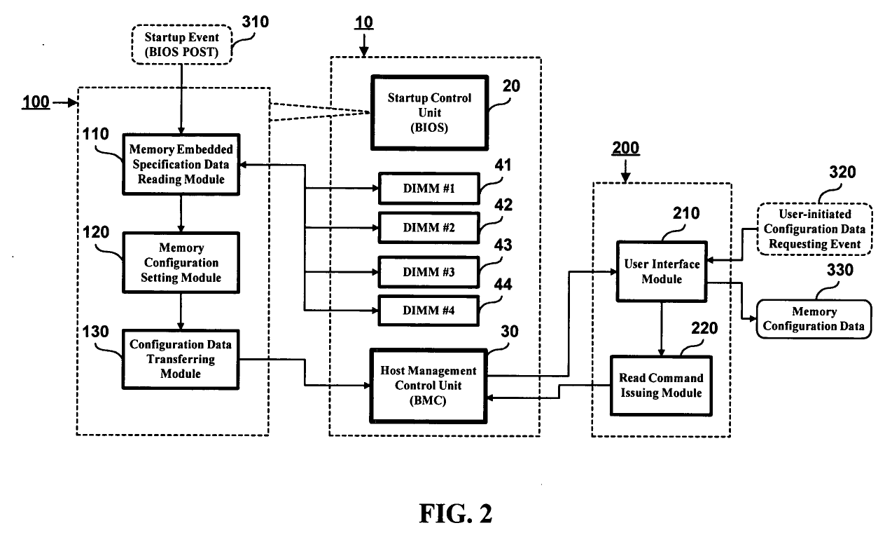

FIG. 1 is a schematic diagram showing the application and distributed architecture of the host computer memory configuration data remote access system according to the invention (as the part enclosed in the dotted box indicated by the reference numeral 60). As shown, the host computer memory configuration data remote access system of the invention 60 is based on a distributed architecture for integration to a client station 50 and a centralized host computer, such as a network server 10, particularly an enterprise-class network server; and wherein as shown in FIG. 2, the network server 10 should be equipped with: (i) a startup control unit, such as a BIOS (Basic Input/Output System) unit 20; (ii) a host management control unit, such as a BMC (Baseboard Management Controller) unit 30; and (iii) a group of memory modules 41, 42, 43, 44, such as DIMM (Dual Inline Memory Module) units (note that in the example shown in FIG. 1, only 4 memory modules are shown for demonstrative purpose; but in practice, the number of memory modules is unrestricted). Further, for simplification of drawings, FIG. 2 shows only those hardware components that are related to the invention).

In actual operation, the host computer memory configuration data remote access system of the invention 60 allows the user of each client station 50 (including local workstations and remote workstations ) linked to the network server 10 to be able to read a set of memory configuration data about the network server 10 remotely via the user's client station 50.

As shown in FIG. 1, the host computer memory configuration data remote access system of the invention 60 is based on a distributed architecture comprising 2 separate units: (A) a host-side unit 100 for installation on the network server 10; and (B) a client-side unit 200 for installation on each client station 50; and wherein as shown in FIG. 2, the host-side unit 100 includes: (A1) a memory embedded specification data reading module 110; (A2) a memory configuration setting module 120; and (A3) a configuration data transferring module 130; while the client-side unit 200 includes: (B1) a user interface module 210; and (B2) a read command issuing module 220. In practical implementation, the host-side unit 100 can be realized by firmware-based computer code and integrated as an add-on module to the BIOS unit 20 on the network server 10, while the client-side unit 200 can be realized by software-based computer code and installed on each client station 50.

Firstly, the respective attributes and behaviors of the constituent modules 110, 120, 130 of the host-side unit 100 installed on the network server 10 are described in details in the following.

The memory embedded specification data reading module 110 is capable of being activated in response to a startup event 310 on the network server 10, i.e., when the BIOS unit 20 is performing a POST (Power On Self Test) procedure after the network server 10 is powered on, and which is capable of responding to the startup event 310 by reading a set of memory specification data that is pre-embedded in each of the DIMM modules 41, 42, 43, 44 installed on the network server 10. In practice, standard DIMM units are internally provided with a memory specification data storage area called SPD (Serial Presence Detect) for storing a set of memory specification data about the associated DIMM unit, such as memory capacity, operating frequency, serial number, manufacturer, and so on. Therefore, the memory embedded specification data reading module 110 is designed to gain access to the embedded SPD data in the DIMM modules 41, 42, 43, 44 to learn the specification of each of the DIMM modules 41, 42, 43,44.

The memory configuration setting module 120 is capable of setting up a system configuration for the DIMM modules 41, 42, 43, 44 based on the SPD memory specification data retrieved from these DIMM modules 41, 42, 43, 44 by the memory embedded specification data reading module 110. For example, based on the required memory capacity of the network server 10 and the SPD data, the memory configuration setting module 120 will perform a series of memory configuring tasks, such as automatically setting the DIMM modules 41, 42, 43, 44 to operate in either single-channel access mode, dual-channel access mode, mirror mode, or backup mode; finding each failed DIMM module (if any) and setting each failed DIMM module to failure mode; setting each surplus DIMM module (if any, in the case that the total capacity of the DIMM modules 41, 42, 43, 44 exceeds required capacity) to disabled mode; and so on. After the configuration is completed, the memory configuration setting module 120 will collect and store all the related parameters and data about the memory configuration in a file named, for example, by HOST MEMORY_CONFIG_DATA.

The configuration data transferring module 130 is capable of transferring the HOST_MEMORY_CONFIG_DATA memory configuration data file generated by the memory configuration setting module 120 from the BIOS unit 20 to the BMC unit 30 for temporary storage in the BMC unit 30. In practical implementation, this action is carried out by using an IPMI-specific customized memory configuration data write command named IPMI OEM CMD. HOST_MEMORY_CONFIG WRITE. This write command includes the following 6 parameters:
Parameter #1: RAS mode (single-channel access mode/dual-channel access mode/ mirror mode/backup mode);
Parameter #2: CH1 DIMM status (usable/failure/disabled/backup);
Parameter #3: CH2 DIMM status (usable/failure/disabled/backup);
Parameter #4: CH3 DIMM status (usable/failure/disabled/backup);
Parameter #5: CH4 DIMM status (usable/failure/disabled/backup);
Parameter #6: total DIMM capacity.

Next, the respective attributes and behaviors of the constituent modules 210, 220 of the client-side unit 200 installed on each client station 50 are described in details in the following.

The user interface module 210 is installed on the client station 50 for providing a user interface for the user to operate the host computer memory configuration data remote access system of the invention 60; i.e., when the user at the client station 50 wants to learn the memory configuration of the network server 10, the user can activate the user interface module 210 and use it to launch a user-initiated configuration data requesting event 320 to request the display of the memory configuration data about the network server 10 on the client station 50. The user interface module 210 will respond to the user-initiated configuration data requesting event 320 by issuing a configuration data read requesting message to the read command issuing module 220.

The read command issuing module 220 is capable of responding to the configuration data read requesting message from the user interface module 210 by issuing a configuration data read command, such as an IPMI-specific customized configuration data read command named “IPMI OEM CMD: HOST_MEMORY_CONFIG READ, to the BMC unit 30 on the network server 10. This command will cause the BMC unit 30 to respond by transferring the memory configuration data stored therein to the user interface module 210 for the user interface module 210 to display the memory configuration data in a human-readable form, such as text form, on the monitor screen 51 of the client station 50, thereby allowing the user at the client station 50 to learn the memory configuration of the network server 10.

The following is a detailed description of a practical example of the application of the host computer memory configuration data remote access system of the invention 60 during actual operation.

Referring to FIG. 1 together with FIG. 2, in actual operation, when the network server 10 is powered on and undergoes a booting process (i.e., when a startup event 310 occurs on the network server 10), it will cause the host computer memory configuration data remote access system of the invention 60 to start to function by first activating the memory embedded specification data reading module 110 in the host-side unit 100 installed on the network server 10 to read a set of pre-embedded memory specification data, i.e., SPD data, in each of the DIMM modules 41, 42, 43, 44 installed on the network server 10. Next, the memory configuration setting module 120 is activated to set up a system configuration for the DIMM modules 41,42, 43, 44 based on the SPD data retrieved from these DIMM modules 41, 42, 43, 44, and then collect and store all the related parameters and data about the memory configuration in a file named by HOST_MEMORY_{—CONFIG}_DATA. Based on the required memory capacity of the network server 10 and the SPD data, the memory configuration setting module 120 will perform a series of memory configuring tasks as automatically setting the DIMM modules 41, 42, 43, 44 to operate in either single-channel access mode, dual-channel access mode, mirror mode, or backup mode; finding each failed DIMM module (if any) and setting each failed DIMM module to failure mode; setting each surplus DIMM module (if any, in the case that the total capacity of the DIMM modules 41, 42, 43, 44 exceeds required capacity) to disabled mode; and so on. Subsequently, the configuration data transferring module 130 is activated by an IPMI-specific customized memory configuration data write command named HOST_MEMORY_CONFIG WRITE to transfer the HOST_MEMORY_CONFIG_DATA memory configuration data file from the BIOS unit 20 to the BMC unit 30 for temporary storage in the BMC unit 30.

After the network server 10 has completed the booting process and started to operate normally, if any network system management personnel wants to learn the current memory configuration of the network server 10, the management personnel can utilize a client station 50 (which can be either a local workstation or a remote workstation) to start up the client-side unit 200 and utilize the user interface module 210 to launch a user-initiated configuration data requesting event 302, causing the user interface module 210 to respond by issuing a configuration data read requesting message to the read command issuing module 220. In response, the read command issuing module 220 issues an IPMI-specific customized configuration data read command HOST_MEMORY_CONFIG READ to the BMC unit 30 on the network server 10. This read command will cause the BMC unit 30 to respond by transferring the memory configuration data 330 stored therein to the user interface module 210 for the user interface module 210 to display the memory configuration data in a human-readable form, such as text form, on the monitor screen 51 of the client station 50, thereby allowing the user at the client station 50 to learn the memory configuration of the network server 10.

In conclusion, the invention provides a host computer memory configuration data remote access method and system which is designed for use with a client station and a host computer for the purpose of allowing a user at the client station to learn the current memory configuration of the host computer via the client station; and which is characterized by the capability of reading a set of embedded memory specification data (such DIMM SPD data) from all the DIMM modules currently installed on the host computer, then using these memory specification data to automatically set up a suitable configuration for these memory modules, and subsequently transferring the memory configuration data from the BIOS unit to a BMC unit that is used to control the linking of the client station to the host computer, such that the client station can retrieve the memory configuration data from the BMC unit. This feature allows network system management personnel to conveniently and quickly gain access to and learn the memory configuration of the host computer from a client station linked to the host computer. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A host computer memory configuration data remote access method for use on a client station and a host computer equipped with a startup control unit, a host management control unit, and a group of memory modules, for the purpose of allowing the client station to gain access to a set of memory configuration data about the memory modules on the host computer;
the host computer memory configuration data remote access method comprising:
on the host computer, responding to a startup event on the host computer by reading a set of memory embedded specification data from the memory modules installed on the host computer;
on the host computer, configuring the memory modules based on the memory embedded specification data retrieved from the memory modules and generating a set of memory configuration data based on the configuration of the memory modules;
on the host computer, transferring the memory configuration data from the startup control unit to the host management control unit for storage in the host management control unit by way of a customized memory configuration data write command;
on the client station, responding to a user-initiated memory configuration data read requesting event by issuing a configuration data read requesting message; and
on the client station, responding to the configuration data read requesting message by issuing a customized configuration data read command to the host management control unit on the host computer, causing the host management control unit to respond by transferring the memory configuration data stored therein to the client station for display in a human-readable form on the client station.

2. The host computer memory configuration data remote access method of claim 1, wherein the host computer is a network server.

3. The host computer memory configuration data remote access method of claim 1, wherein the startup control unit is a BIOS (Basic Input/Output System) module.

4. The host computer memory configuration data remote access method of claim 1, wherein the host management control unit is a BMC (Baseboard Management Controller) module.

5. The host computer memory configuration data remote access method of claim 1, wherein the memory modules are each a DIMM (Dual Inline Memory Module) unit.

6. A host computer memory configuration data remote access system for use with a client station and a host computer equipped with a startup control unit, a host management control unit, and a group of memory modules, for the purpose of allowing the client station to gain access to a set of memory configuration data about the memory modules on the host computer;
the host computer memory configuration data remote access system comprising a host-side unit and a client-side unit;
wherein
the host-side unit is installed on the host computer, and which includes:
a memory embedded specification data reading module, which is capable of responding to a startup event on the host computer by reading a set of memory embedded specification data from the memory modules installed on the host computer;
a memory configuration setting module, which is capable of configuring the memory modules based on the memory embedded specification data retrieved from the memory modules by the memory embedded specification data reading module, and further capable of generating a set of memory configuration data based on the configuration of the memory modules; and
a configuration data transferring module, which is capable of transferring the memory configuration data generated by the memory configuration setting module from the startup control unit to the host management control unit for storage in the host management control unit by way of a customized memory configuration data write command; and
and wherein
the client-side unit is installed the client station, and which includes:
a user interface module, which is capable of responding to a user-initiated memory configuration data read requesting event by issuing a configuration data read requesting message; and
a read command issuing module, which is capable of responding to the configuration data read requesting message by issuing a customized configuration data read command to the host management control unit on the host computer, causing the host management control unit to respond by transferring the memory configuration data stored therein to the user interface module for the user interface module to display the memory configuration data in a human-readable form on the client station.

7. The host computer memory configuration data remote access system of claim 6, wherein the host computer is a network server.

8. The host computer memory configuration data remote access system of claim 6, wherein the startup control unit is a BIOS (Basic Input/Output System) module.

9. The host computer memory configuration data remote access system of claim 6, wherein the host management control unit is a BMC (Baseboard Management Controller) unit.

10. The host computer memory configuration data remote access system of claim 6, wherein the memory modules are each a DIMM (Dual Inline Memory Module) unit.
